(19) United States
(12) Patent Application Publication
(10) Pub. No.: US 2024/0060206 A1
(43) Pub. Date: Feb. 22, 2024

(54) PROCESS FOR MANUFACTURING A MONOCRYSTALLINE CRYSTAL, IN PARTICULAR A SAPPHIRE

(71) Applicant: FAMETEC GmbH, Leonding (AT)

(72) Inventors: Robert EBNER, Leonding (AT); Jong Kwan PARK, Leonding (AT); Gourav SEN, Leonding (AT); Ghassan BARBAR, Neunkirchen (DE)

(73) Assignee: FAMETEC GmbH, Leonding (AT)

(21) Appl. No.: 18/270,095

(22) PCT Filed: Dec. 28, 2021
(86) PCT No.: PCT/AT2021/060489

§ 371 Date: Jun. 28, 2023

(30) Foreign Application Priority Data
Dec. 29, 2020 (AT) A 51145/2020

(51) Int. Cl. C30B 11/14; C30B 11/00; C30B 11/02

(52) U.S. Cl. CPC C30B 11/14; C30B 11/001; C30B 11/002; C30B 11/003; C30B 11/02

(57) ABSTRACT

In a method of manufacturing a monocrystalline crystal, in particular a sapphire, a monocrystalline seed crystal is arranged in a base region of a crucible with a cylindrical jacket-shaped crucible wall or forms a base of the crucible and a crystallographic c-axis of the seed crystal is aligned corresponding to a longitudinal axis of the crucible extending in the direction of the top of the crucible wall, whereupon a base material is arranged above the seed crystal in the crucible and melted, crystal growth taking place progressively in the direction of the c-axis by crystallization at a boundary layer between melted base material and seed crystal.

The invention relates to a method for manufacturing a monocrystalline crystal or several single crystals in a chamber of a kiln, in particular a sapphire.

Producing large single crystals, such as those used in the production of wafers, is known from the prior art, for example from KR 10 2017-0026734.

Producing large single crystals, such as those used in the production of wafers, is known from the prior art, for example from KR 10 2017-0026734. As is known, the quality requirements of these crystals is very high, meaning that a wide variety of methods and devices for producing these are described in the prior art. One method type envisages providing and melting the “raw material” in a crucible. The single crystal is then created in the crucible itself by way of controlled cooling of the melt. The devices used for this are configured in a great variety of ways. US 2013/152851 A1 describes a device for manufacturing an Si single crystal having an isolation chamber, in which the crucible and heating elements are arranged next to and above the crucible, for example. A reflector is further arranged between the upper heating element and the crucible in order to reflect the heat energy radiated from the crucible back to into the crucible and therefore improve the energy efficiency in growing the single crystal.

WO 2012/067372 A2 describes a device for manufacturing a sapphire single crystal, comprising a chamber, a crucible arranged therein, in which the alumina melt is contained, a heater arranged outside of the crucible to heat the crucible and a heat supply unit arranged above a growing single crystal in the crucible to provide heat to the single crystal. This device also provides a reflector, which reflects the heat generated in the chamber to a surface of the single crystal.

The problem of the present invention was to create a single crystal of very high quality which, when cut into wafers, would produce as little waste material as possible and to reduce the energy consumption per single wafer produced overall.

This problem is solved by a method as specified above in accordance with the invention in that a monocrystalline seed crystal is arranged in a base region of a crucible with a cylinder-jacket-shaped crucible wall or forms a base of the crucible and a crystallographic c-axis of the seed crystal is aligned in accordance with a longitudinal axis of the crucible extending in the direction of the top of the crucible wall, whereupon a base material is arranged above the seed crystal in the crucible and melted, a crystal growth by crystallisation taking place at a boundary layer between the melted base material and seed crystal extending in the direction of the c-axis.

Because of the alignment of the c-axis of the seed crystal corresponding to the longitudinal axis of the crucible, the solution in accordance with the invention enables the manufacturing of very high quality wafers. Wafers cut transversely to the c-axis of an ingot formed from the single crystal also have a defined c-axis position, which is a substantial quality feature, especially with regard to optical applications. The solution in accordance with the invention results in less waste because the production of low-quality ingots can be significantly reduced. The overall energy consumption required to produce the single crystals is therefore also reduced.

Several crystals can be grown simultaneously in a kiln by arranging several crucibles in the kiln using the solution in accordance with the invention.

Arranging the c-axis of the seed crystal coincidentally with the longitudinal axis of the crucible has been found to be particularly advantageous.

The solution according to the invention is particularly suitable for manufacturing sapphire. For this reason, it can be intended that Al2O3 is used as a base material according to an advantageous variant of the invention.

According to a further variant of the invention, it can be intended that the seed crystal is configured in a substantially disc-shaped manner
having a first flat side and a second flat side
having a longitudinal centre axis, said longitudinal centre axis configured from the first flat side to the second flat side, wherein the c-axis of the seed crystal is coincidental with the longitudinal centre axis of the seed crystal.

According to a preferred variant of the invention, the position of the c-axis can be marked on the seed crystal.

With regard to efficient heating of the melt or base material contained in the crucible, it can be particularly advantageous to provide the crucible, viewed from the seed crystal, to be upwardly open and a mirror of a melt of the base material to be heated from above by at least one heating element, which is arranged above an open side of the crucible.

In order to ensure the most even heating of the melt, it can be intended that a thermal diffuser for generating even heat distribution is arranged between the heating element and the open side of the crucible.

In order to prevent flaws from forming in the single crystal, it can be intended that the crucible wall has constant thermal conductivity and/or constant mechanical properties over its entire extension.

Furthermore, it can be intended that the crucible wall has an identical surface finish on its crucible inner wall.

Configuring the crucible wall such that it is closed on itself in an annular and seamless manner has been found to be particularly advantageous.

The crucible wall can further have a similar structural composition across its entire extension.

To improve understanding of the invention, it is described in more detail in the following figures.

These show in significantly simplified, schematic representation:

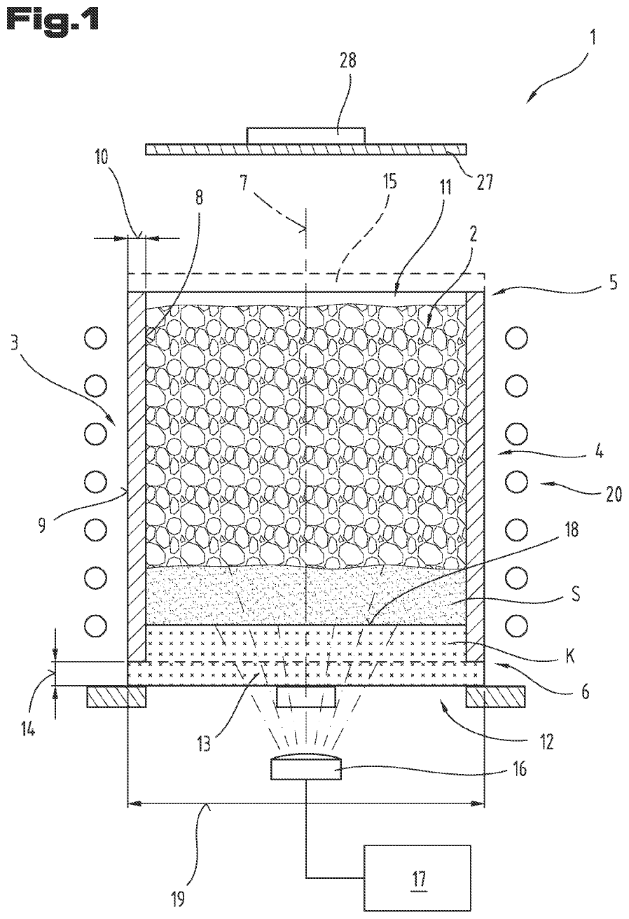

FIG. 1 a first possible embodiment of a device for growing an artificially manufactured sapphire crystal, in a sectional view;

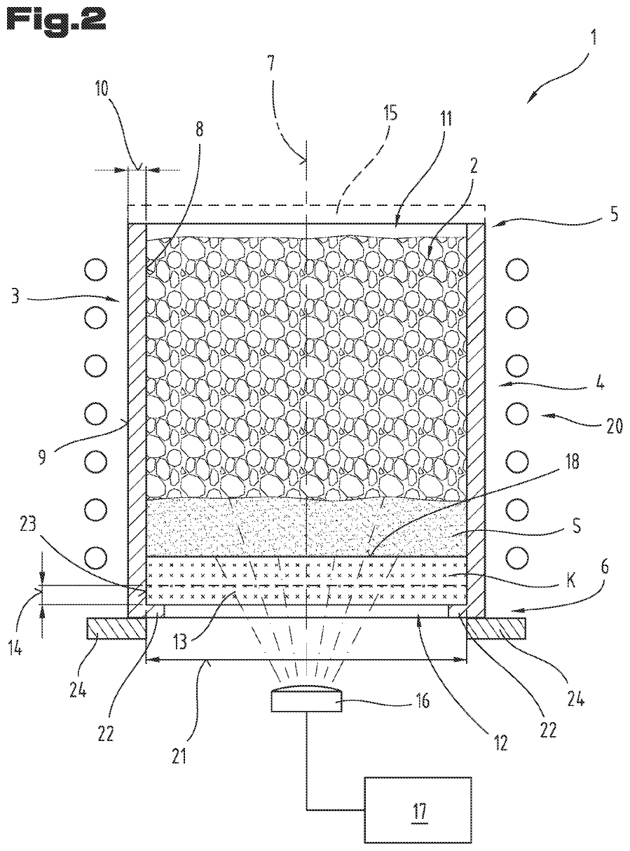

FIG. 2 a second possible embodiment of a device for growing an artificially manufactured sapphire crystal, in a sectional view;

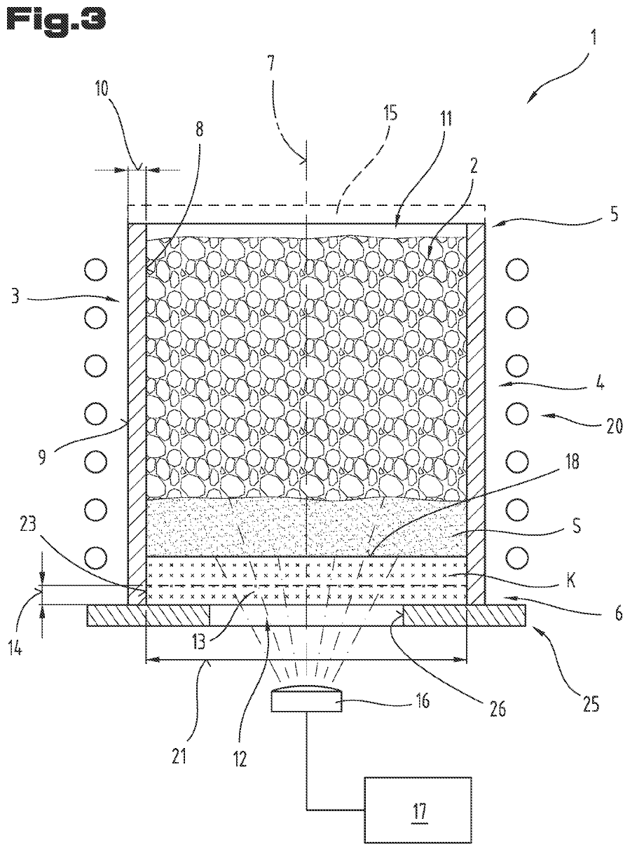

FIG. 3 a third embodiment of a device for growing an artificially manufactured sapphire crystal, in a sectional view.

It is worth noting here that the same parts have been given the same reference numerals or same component configurations in the embodiments described differently, yet the disclosures contained throughout the entire description can be applied analogously to the same parts with the same reference numerals or the same component configurations. The indications of position selected in the description, such as above, below, on the side etc. refer to the figure directly described and shown, and these indications of position can be applied in the same way to the new position should the position change.

FIG. 1 shows a first embodiment of device 1, which serves to or is configured to grow a crystal, in particular an artificially manufactured sapphire crystal. The chemical formula for sapphire is Al2O3 and it occurs naturally, and is used as a gemstone or similar.

Synthetic or artificial manufacturing is performed starting with what is known as the base material 2, which can have a lumpy, grainy, or even powdery structure. Larger pieces can also be used to achieve better bulk density. The base material 2 is placed into a receiving device or receiving container, generally referred to as the crucible 3, where it is melted using heat application as is known in the art.

The melt, hereinafter referred to as “S”, is cooled down, leading to the solidifying and formation of crystal K. Such a crystal “K” is preferably a single crystal form of aluminium ox-ide (Al2O3). The synthetically manufactured sapphire crystal “K” has a hardness of 9 on the Mohs scale. Furthermore, products made from it such as wafers, watch faces, housings, LEDs or similar, have high scratch resistance. “K” crystals with crystal clear properties or depending on additives with a coloured appearance are preferably formed.

Device 1 comprises a crucible wall 4, said wall having a first end portion 5 and a second end portion 6 arranged at a distance from the first wall. A longitudinal axis 7 extends between the two end portions 5 and 6. The first end portion 5 has an open configuration in this embodiment. When longitudinal axis 7 is aligned perpendicularly, the second end portion 6 forms the baseside end portion and has an entirely or predominantly open configuration. The crucible wall 4 is fundamentally tubular and can have a large variety of cross-sectional shapes in relation to the longitudinal axis 7. The cross-sectional shape depends on the cross-section of the crystal “K” to be manufactured. For example, the inner cross section can be round, oval, or polygonal. The polygonal cross section can, for example, be formed by a square, a rectangle, a pentagon, a hexagon, an octagon or the like.

Crucible wall 4 defines a crucible wall inner surface 8 and a crucible wall outer surface 9, wherein when viewed in a radial direction the two crucible wall surfaces 8 and 9 form a crucible wall thickness 10.

To form a receiving area 11, the crucible wall 4 has a closed configuration with a crucible base 12 on the base side of its second end portion 6. The crucible wall 4 and the crucible base 12 thereby define the receiving area 11.

In this embodiment and the embodiments described hereinafter, it is provided for that the crucible base 12 itself is or shall be formed predominantly exclusively from a plate 13 made from a previously artificially manufactured sapphire crystal K. It is preferred, however, that the entire crucible base 12 is exclusively formed from plate 13, itself made from the previously artificially manufactured sapphire crystal K. The plate 13 which forms the crucible base 12 thereby forms a seed crystal for the sapphire crystal “K” to be manufactured. The dividing line between the plate 13 and the already newly manufactured sapphire crystal “K” was depicted respectively with a dashed line, because at the beginning of the melting process of the base material 2 and the formation of melt “S”, the surface of the plate 13 which is facing the receiving area 11 is at least partially or entirely melted and with progressing cooling and crystallisation, a conglomerate monolithic sapphire crystal “K” is formed.

The plate 13 that forms the crucible base 12 can have a plate thickness derived from a plate thickness value range with a lower limit of 0.5 mm, in particular 1 mm, and an upper limit of 5 mm, in particular 2 mm.

Furthermore, the open first end portion 5 of the crucible wall 4 can be covered by a crucible lid 15. A material from the group containing iridium (Ir), tungsten (W), and molybdenum (Mo) can be used a possible material for forming the crucible wall 4 and/or crucible lid 15.

Since the sapphire crystal “K” as well as the plate 13 that forms the crucible base 12 usually are or become crystal clear or transparent, it is possible to carry out a variety of measurements in receiving area 11 through plate 13. To do so, at least one sensor 16 shall be provided depending on the measurement to be carried out. The at least one sensor 16 is arranged on the side of plate 13 that forms the crucible base 12 that is not facing receiving area 11 and is represented in a simplified manner. The sensor 16 can have a communication link with a control device 17 and transmit the measurement value(s) obtained to said control device.

The sensor 16 can, for example, be configured to determine the relative position of a boundary layer 18 between the solidified sapphire crystal “K” and melt “S”, which is still located above and is made from the base material. The measurement signals emitted by the sensor 16 are indicated/represented by dashed lines up to the boundary layer 18. It would, however, also be possible to determine the position of the melt surface within the receiving area 11 using said sensor 16 and/or a further sensor not depicted here. In this embodiment and the embodiments described hereinafter, the measuring signals that end at the melt surface are indicated by dashed and dotted lines. It would, however, also be possible to detect the respective position or height location using the same sensor 16 and the determined different path duration of the measuring signals to the boundary layer 18 between the solidified sapphire crystal “K” and the melt “S” which is still located above, or up to the melt surface.

The sensor 16, which can also be designated as a detector, probe, measuring probe, or transducer, is a technical component that can detect certain physical or chemical properties and/or the material composition of its surroundings, either qualitatively or as a quantitative parameter. These values are detected using physical, chemical, or biological effects and converted into an electrical signal that can be processed further and where necessary transmitted to the control device 17. The device 1 and the process flow can be regulated and controlled using the control device 17.

It is further shown that when the longitudinal axis 7 of the crucible wall 4 is aligned perpendicularly, it can be supported on its base-side second end portion 6, namely its base-side crucible front surface, on the plate 13 that forms the crucible base 12 formed from the previously artificially manufactured sapphire crystal K. The external dimension of the plate 13 shall therefore be formed larger than the thin internal dimension of the crucible wall inner surface. Thus, the plate 13 that forms the crucible base 12 can, for example, have an external dimension 19 that corresponds to a cross-sectional dimension as defined by the crucible wall outer surface 9. A radial protrusion of the plate beyond the external dimension of the crucible wall 4 can thereby be prevented. To enable demoulding and possible support of the crucible wall 4 in its base-side second end portion 6, as represented by dashed lines, the external dimension 19 of the plate 13 can be selected as smaller than the external cross-sectional dimension defined by the crucible wall external dimension 9.

Furthermore, using the plate 13, the crucible wall 4 can be supported on a supporting device that is not specified in more detail here. In this embodiment, the support device is formed by separate support elements, preferably arranged across the circumference. A simplified schematic diagram indicates a heating device 20 outside the crucible wall 4, said heating device being usable to melt the base material 2 as placed in the receiving area 11 to a melt bath, said melt “S” crystallising and solidifying to form sapphire crystal “K” when it cools.

FIG. 2 shows a further, optionally independent, embodiment of device 1 wherein again the same reference numerals or component designations as in the preceding FIG. 1 are used for identical parts. To avoid unnecessary repetitions, reference is made to the detailed description in preceding FIG. 1.

The device 1 itself comprises the crucible wall 4, the crucible lid 15 where required and the crucible base 12 formed of the crystalline plate 13.

The plate 13 that forms the crucible base 12 has a maximum external dimension 19 here that corresponds to a cross-sectional dimension defined by the crucible wall inner surface 8. Furthermore, the plate 13 is inserted into the base area of the receiving area 11.

In order to achieve positioned holding of the plate 13 relative to the crucible wall 4, several support extensions 22 can be provided for. The support extensions 22 protrude over the crucible wall inner surface 8 in the direction of the longitudinal axis 7 and are preferably arranged across the circumference of the crucible wall inner surface 7. Furthermore, the support extensions 22 can form an integral part of the crucible wall 4 and can be made from the same material as the crucible wall 4. The term integral is understood here as meaning that the support extensions 22 form one piece together with the crucible wall 4.

If the support extensions 22 are provided, the plate 13 forming the crucible base 12 is supported on the support extensions 22 on the side facing the respective open first end portion 5. The support extensions 22 are usually arranged as protrusions or projections. It would, however, also be possible to form the support extensions 22 from a support flange running along the inner circumference.

The outer dimension 19 of the plate 13 that forms the crucible base 12 can be selected such that it constantly forms a seal on the inner surface of the crucible wall 8 with its outer circumferential front surface 23. The plate 13 shall form a fluid seal on the inner surface of the crucible wall 8.

Again here the previously described sensor 16 can be provided. As the plate 13 is preferably completely inserted into the receiving area 11, the carrying support of the crucible wall 4 with its base-side second end portion 6 can be supported by at least one supporting element 24.

FIG. 3 shows a further, optionally independent, embodiment of device 1 wherein again the same reference numerals or component designations as in the preceding FIGS. 1 and 2 are used for identical parts. To avoid unnecessary repetitions, reference is made to the detailed description in preceding FIGS. 1 and 2.

The device 1 itself comprises the crucible wall 4, the crucible lid 15 where required and the crucible base 12 formed of the crystalline plate 13.

The plate 13 that forms the crucible base 12 again here has a maximum external dimension 19 corresponding to a cross-sectional dimension as defined by the inner surface of the crucible wall 8. Furthermore, the plate 13 is inserted into the base area of the receiving area 11. The outer dimension 19 of the plate 13 that forms the crucible base 12 can be selected such that its outer circumferential front surface 23 is constantly in contact and forms a seal with the inner crucible wall surface 8. The plate 13 shall form a fluid seal on the inner surface of the crucible wall 8.

Contrary to the previously described embodiment in FIG. 2, no support extensions 22 are provided for the positioning of plate 13 on the crucible wall 4.

It is intended that the crucible wall 4 and the plate 13 that forms the crucible base 12 are jointly placed on a component of device 1 generally designated as a support device 25. The support device 25 can be formed of individual supporting elements or by a single support plate. Depending on the configuration of the support device 25, it shall have at least one interspersion 26 that passes through the support device 25 in the direction of the longitudinal axis 7. The at least one interspersion 26 serves to allow viewing of the receiving area 11 of the previously described sensor 16. The determination or various determinations can thereby be performed with the sensors 16 provided for that purpose.

Thereby not only the relative position of the previously described boundary layer 18 between the already formed sapphire crystal “K” and the melt “S” can be determined, but also or additionally the quality and/or purity of the already formed sapphire crystal K. Should, for example, false crystallisation and/or a quality deviation be identified, the further crystallisation process and the melting of the base material 2 can be terminated, such that a high proportion of energy costs can be saved.

Due to the predominantly not closed and therefore also open configuration of the crucible wall 4 in the base-side end portion 6, the finished, crystallised sapphire crystal “K” can either be removed through the open, base-side second end portion 6, as shown and described in FIGS. 1 and 3, or by applying a base-side pressure force (demoulding force) to the finished, crystallised sapphire crystal “K” in the direction of the open first end portion 5 and thereby be demoulded from the crucible wall 4.

The method for growing the artificially manufactured sapphire crystal “K” can preferably be performed by using or applying device 1 with the crucible wall 4 and the plate 13 that forms the crucible base 12 made from the crystalline material as a seed crystal. As an alternative to the crucibles shown in FIGS. 1 and 3 a crucible with a closed base can be used, wherein the seed crystal or the plate 13 is then inserted into the crucible.

At least the following steps for performing the method are provided for:

Arrangement of a monocrystalline seed crystal made from sapphire in a base area of the crucible 3 and alignment of a crystallographic c-axis of the seed crystal or the plate 13 with a longitudinal axis 7 of the crucible which extends up the crucible wall 4. The crystallographic c-axis is hereby understood as the crystal's optical axis along which each polarisation component of a light beam is subject to the same refractive index. Arrangement of the base material 2, in particular Al2O3, in the crucible 3 on the seed crystal and melting of the base material 2, wherein crystal growth through crystallisation on a boundary layer between the melted base material 2 and the seed crystal occurs progressively along the c-axis. The seed crystal is preferably arranged such that its c-axis is arranged coincidentally with the crucible's longitudinal axis.

It should be pointed out here that several crystals can also be grown at the same time in one kiln by arranging several crucibles 3 in the kiln or a chamber of the kiln. If several crystals are grown simultaneously in one kiln, the method described herein is performed for each crystal. Simultaneously growing several crystals in one kiln is particularly advantageous regarding energy requirements.

The seed crystal is configured in a substantially disc-shaped manner and has a first flat side, a second flat side and a longitudinal centre axis, said longitudinal centre axis configured in the direction from the first flat side to the second flat side, wherein the c-axis of the seed crystal is coincidental with the longitudinal centre axis of the seed crystal.

Preferably, the flat side shall have a curvature having a highest and a lowest point in relation to the longitudinal centre axis, wherein a distance between the highest point and the lowest point of the curvature to the longitudinal centre axis is smaller than 7 μm. The curvature of the seed crystal can be concave or convex. The curvature hereby relates to the curvature of a seed crystal, i.e. following one-sided or both-sided polishing of the seed crystal.

The position of the c-axis can be marked on the seed crystal, in particular on the side not facing the direction of crystal growth, for example with a dot or notch. The position of the c-axis can also be marked accordingly on the surface of the finished ingot that is opposite the seed crystal. Furthermore, the positions of the wafers on the finished ingot can be marked so as to simplify cutting the wafers out of the ingot.

Because the crucible or the crucibles 3 is or are open at the top when viewed from the seed crystal, when the lid 15 is removed, a mirror of a melt of the base material can be heated directly from above by means of at least one upper heating element when the crucible or the crucibles 3 are not covered, said heating element is designated reference numeral 28 in FIG. 1 and can be arranged above an open side of the crucible 4 and directly heated from above, wherein preferably a heat diffuser element 27, for example a diffuser plate, can be arranged between the heating element 28 and the open, upper side of the crucible in order to produce a uniform heat distribution directly at the heating element.

Furthermore, the crucible wall 4 of each crucible 3 can have a constant thermal conductivity and/or the same optical and/or the same mechanical properties along its entire extension. The crucible wall 4 can also have an identical surface finish on its crucible inner wall 8. Furthermore, the cylindrical crucible wall 4 can be annularly closed on itself and seamless, and have an identical structural construction along its entire extension. The crucible wall 4 thereby preferably has no vertically extending welding or joining spots.

The seamless and homogeneous construction of the crucible wall 4 avoids local weakening of the material as is the case with a weld seam. In particular, flaws in the single crystal that form along the weld seam during crystal growth can be prevented. A centrifugal casting method is particularly suitable for forming the crucible wall 4. The crucible wall 4 can then later be fused with the crucible base 12. Where the crucible base 12 is formed by the seed crystal itself, the crucible wall 4 can be placed on the crucible base. Where the crucible base 12 is formed from the same or a similar material as the crucible wall 4, the crucible wall 4 can be fused with the crucible base 12, for example by welding. In this case, the seed crystal can be inserted into the crucible 4.

The single crystal to be manufactured preferably has an outer diameter/cross-sectional surface which corresponds to the inner diameter/interior geometry of the crucible 3. The resulting single crystal thereby preferably completely fills the cross-sectional surface of the crucible 3. The single crystal is therefore preferably not removed from the crucible. For example, the finished single crystal can have a diameter of between 5 cm and 50 cm and a height of between 5 cm and 80 cm. It should, however, be pointed out that these values are illustrative and are not to be understood as limiting the scope of protection.

By cutting transversely to the longitudinal axis 7, the single crystal ingot obtained can be cut into wafers, which are substantially disc shaped
have a first flat side and a second flat side
have a longitudinal centre axis, which is configured in the direction from the first flat side to the second flat side
wherein the at least one flat side has a curvature, said curvature having a highest point and a lowest point in relation to the longitudinal centre axis wherein a distance between the highest point and the lowest point of the curvature is 7 μm in relation to the longitudinal centre axis.

The longitudinal centre axis of the wafer is also formed by the c-axis, wherein the position of the c-axis can be optically marked on the wafer using a point, for example.

The curvature of the wafer can be concave or convex.

Using the previously described sensor 16, optionally in combination with the control device 17, the sensor 16 can determine, e.g., the relative position of the boundary layer 18 between the already solidified sapphire crystal “K” and the melt “S”, through plate 13 that forms crucible base 12.

This is possible because the crystal plate that forms the seed crystal is at least transparent or translucent, or even crystal clear. A passage for measuring beams emitted by the sensor 16 through the plate 13 is therefore allowed for.

All value ranges specified in the current description are to be understood such that they include any and all sub-ranges, e.g., the specification 1 to 10 is to be understood such that all sub-ranges, starting from the lower limit 1 and the upper limit 10 are included, i.e., all sub-ranges begin with a lower limit of 1 or more and end at an upper limit of 10 or less, e.g., 1 to 1.7, or 3.2 to 8.1, or 5.5 to 10.

As a matter of form and by way of conclusion, it is noted that, to improve understanding of the structure, elements have partially not been shown to scale and/or enlarged and/or shrunk.

### LIST OF REFERENCE NUMERALS

1 Device
2 Base material
3 Crucible
4 Crucible wall
5 First end portion
6 Second end portion
7 Longitudinal axis
8 Crucible wall inner surface
9 Crucible wall outer surface
10 Crucible wall thickness
11 Receiving area
12 Crucible base
13 Plate
14 Plate thickness
15 Crucible lid
16 Sensor
17 Control device
18 Boundary layer
19 External dimension
20 Heating device
21 External dimension
22 Support extensions
23 Circumferential front surface
24 Support element
25 Support device
26 Interspersion
27 Heat diffuser element
28 Heating element

1. A method for producing at least one monocrystalline sapphire, wherein a monocrystalline seed crystal is arranged in a base region of a crucible (3) with a cylindrical jacket-shaped crucible wall (4) or forms a base of the crucible (3) and a crystallographic c-axis of the seed crystal is aligned corresponding to a longitudinal axis of the crucible extending in the direction of the top of the crucible wall, whereupon a base material is arranged above the seed crystal in the crucible and melted, crystal growth taking place progressively in the direction of the c-axis by crystallization at a boundary layer between melted base material and seed crystal, wherein the crucible is open upwardly viewed from the seed crystal and a mirror of a melt of the base material is heated from above by at least one upper heating element (28), which is arranged above an open, upper side of the crucible (4).

2. The method according to claim 1, wherein the c-axis of the seed crystal is coincidentally arranged with the longitudinal axis (7) of the crucible (3).

3. The method according to claim 1, wherein Al2O3 is used as base material.

4. The method according to claim 1, wherein the seed crystal is configured in a substantially disc-shaped manner
having a first flat side and a second flat side;
having a longitudinal center axis, said longitudinal center axis extending from the first flat side to the second flat side, wherein the c-axis of the seed crystal is coincidental with the longitudinal center axis of the seed crystal.

5. The method according to claim 1, wherein the position of the c-axis is marked on the seed crystal.

6. (canceled)

7. The method according to claim 1, wherein a heat diffuser element (27) for producing an even heat distribution is arranged between the heating element (28) and the open side of the crucible (4).

8. The method according to claim 1, wherein the crucible wall (4) has constant thermal conductivity and/or identical mechanical properties across its entire extension.

9. The method according to claim 1, wherein the crucible wall (4) has an identical surface finish on its crucible inner wall (8).

10. The method according to claim 1, wherein the crucible wall (4) is closed on itself in an annular and seamless configuration.

11. The method according to claim 1, wherein the crucible wall (4) has a similar structural composition across its entire extension.
